(19) United States
(12) Patent Application Publication
(10) Pub. No.: US 2019/0096305 A1
(43) Pub. Date: Mar. 28, 2019

(54) LEVEL SHIFT CIRCUIT, CONTROL METHOD THEREOF, DISPLAY DEVICE AND DRIVE CIRCUIT THEREOF

(71) Applicants: BOE Technology Group Co., Ltd., Beijing (CN); Beijing BOE Display Technology Co., Ltd., Beijing (CN)

(72) Inventors: Shulin Yao, Beijing (CN); Zhihua Sun, Beijing (CN); Xu Zhang, Beijing (CN); Ruipeng Xu, Beijing (CN); Ning Zhang, Beijing (CN)

(73) Assignees: BOE Technology Group Co., Ltd.; Beijing BOE Display Technology Co., Ltd.

(21) Appl. No.: 16/034,454

(22) Filed: Jul. 13, 2018

(30) Foreign Application Priority Data
Sep. 25, 2017 (CN) 201710876689.8

(51) Int. Cl. G09G 3/20; H03K 3/037

(52) U.S. Cl. CPC G09G 3/20; H03K 3/037; G09G 2310/06; G09G 2330/04; G09G 2310/0289

(57) ABSTRACT

A level shift circuit, control method thereof, a display device and a drive circuit thereof are provided. The level shift circuit includes a level shift sub-circuit and a detection sub-circuit. The detection sub-circuit is connected to a signal input end and the level shift sub-circuit, and is configured to detect whether the signals output by the signal output end meet the normal output condition or not. A feedback signal with a first level may be output to the level shift sub-circuit when signals output by the signal output end are detected not to meet the normal output condition. The level shift circuit may stop outputting the signals to the signal output end according to the feedback signal. By arranging the detection sub-circuit to detect whether the output signal meets the normal condition, the gate drive circuit may be effectively protected.

This application claims priority to Chinese Patent Application No. 201710876689.8, filed with the State Intellectual Property Office on Sep. 25, 2017 and titled “LEVEL SHIFT CIRCUIT, CONTROL METHOD THEREOF, DISPLAY DEVICE AND DRIVE CIRCUIT THEREOF,” the entire contents of which are incorporated herein by reference.

### TECHNICAL FIELD

The present disclosure relates to a level shift circuit, control method thereof, a display device and a drive circuit thereof.

### BACKGROUND

When a display device displays an image, it is necessary to use a gate drive circuit for display drive of a pixel unit in a display panel. Since a control signal required by the gate drive circuit is relatively higher in level, a control signal with a relatively lower level generally needs to be converted into a control signal with a relatively higher level through a level shift circuit. Then, the level-converted control signal is output to the gate drive circuit.

In the related art, an overcurrent protection chip that may detect current of the control signal output by the level shift circuit is disposed in the level shift circuit. When detecting the current of the control circuit exceeds threshold current, the overcurrent protection chip will activate overcurrent protection. For example, the overcurrent protection chip may stop outputting the control signal to the gate drive circuit to avoid damaging a device in the gate drive circuit.

However, the overcurrent protection chip may only detect the current level of the output control signal. Thus, its detection mode is relatively monotonous and its protection effect is relatively poorer.

### SUMMARY

The present disclosure provides a level shift circuit, control method thereof, a display device and a drive circuit thereof.

In an aspect, there is provided a level shift circuit, comprising a level shift sub-circuit and at least one detection sub-circuit; the level shift sub-circuit is connected to at least two signal input ends and at least two signal output ends respectively and configured to convert the level of an input signal that is provided by each signal input end and then to output the level-converted input signal to the corresponding signal output end, wherein each signal input end corresponding to one of the signal output ends; each detection sub-circuit is connected to two signal output ends and a feedback signal input end of the level shift sub-circuit respectively and configured to output a feedback signal with a first level to the level shift sub-circuit when detecting that signals output by the two signal output ends connected thereto do not meet a normal output condition; and the level shift sub-circuit is further configured to stop outputting the signals to the two signal output ends that are connected to any of the detection sub-circuits when detecting the feedback signal with the first level sent by any of the detection sub-circuits.

Optionally, the level shift sub-circuit is connected to at least one group of signal input ends and at least one group of signal output ends respectively, each group of signal input ends comprising two signal input ends, input signals that are provided by the two signal input ends of each group of signal input ends being complementary, each group of signal output ends comprising two signal output ends, and each detection sub-circuit is connected to one group of signal output ends respectively; and the normal output condition includes that the signals output by the two signal output ends are complementary.

Optionally, input signals that are provided by the two signal input ends of each group of signal input ends are the same in frequency but opposite in phase, and the normal output condition includes that the signals output by the two signal output ends are the same in frequency but opposite in phase.

Optionally, the level shift sub-circuit is connected to two groups of signal input ends and two groups of signal output ends respectively; and the level shift circuit comprises two detection sub-circuits each of which is connected to one group of signal output ends respectively.

Optionally, each detection sub-circuit is further configured to output a feedback signal with a second level to the level shift sub-circuit when detecting that the signals output by the two signal output ends connected thereto meet the normal output condition; and the level shift sub-circuit is further configured to output signals to two signal output ends that are connected to any of the detection sub-circuits when detecting the feedback signal with the second level sent by any of the detection sub-circuits.

Optionally, each detection sub-circuit comprises a comparator; two input ends of the comparator are respectively connected to two signal output ends, an output end of the comparator is connected to a feedback signal input end of the level shift sub-circuit, the comparator is configured to detect the levels of signals output by the two signal output ends, to output a feedback signal with a first level to the level shift sub-circuit when detecting that the levels of the signals output by the two signal output ends do not meet the normal output condition, and to output a feedback signal with a second level to the level shift sub-circuit when detecting the levels of the signals output by the two signal output ends meet the normal output condition; and the normal output condition includes that the level of the signal output by one signal output end is within a high-level range and the level of the signal output by the other signal output end is within a low-level range.

Optionally, the comparator comprises a NAND gate; and two input ends of the NAND gate are respectively connected to two signal output ends, and an output end of the NAND gate is connected to the feedback signal input end of the level shift sub-circuit.

Optionally, the level shift sub-circuit is further configured to stop outputting signals to all the signal output ends when detecting the feedback signal with the first level sent by any of the detection sub-circuits.

Optionally, the level shift circuit further comprises a logic sub-circuit; herein, the level shift sub-circuit is connected to the at least two signal input ends through the logic sub-circuit, and the logic sub-circuit is configured to process the input signal provided by each signal input end and then to provide the level shift sub-circuit with the processed input signals.

Optionally, the level shift sub-circuit is further connected to a first power supply end and a second power supply end respectively, the first power supply end being configured to provide a first power supply signal with a third level, the second power supply end being configured to provide a second power supply signal with a fourth level and the third level being a high level relative to the fourth level; and the level shift sub-circuit is configured to convert the level of the input signal provided by each signal input end based on the first power supply signal and the second power supply signal.

In another aspect, there is provided a control method of a level shift circuit, wherein the level shift circuit comprises a level shift sub-circuit and at least one detection sub-circuit; the level shift sub-circuit is connected to at least two signal input ends and at least two signal output ends respectively, and each detection sub-circuit is connected to two signal output ends and the level shift sub-circuit respectively; and the control method comprises: detecting whether signals output by the two signal output ends that are connected to each detection sub-circuit meet a normal output condition or not; and stopping outputting signals to two signal output ends that are connected to any of the detection sub-circuit when detecting that the signals output by two signal output ends that are connected to any of the detection sub-circuit do not meet the normal output condition.

Optionally, the level shift sub-circuit is connected to at least one group of signal input ends and at least one group of signal output ends, each group of signal input ends comprising two signal input ends respectively, input signals that are provided by the two signal input ends of each group of signal input ends are complementary; and the normal output condition includes that the signals output by the two signal output ends are complementary.

Optionally, input signals that are provided by the two signal input ends of each group of signal input ends are the same in frequency but opposite in phase; and the normal output condition includes that the signals output by the two signal output ends are the same in frequency but opposite in phase.

Optionally, after said detecting whether the signals output by the two signal output ends that are connected to each detection sub-circuit meet the normal output condition or not, further comprising: outputting signals to two signal output ends that are connected to any of the detection sub-circuits when detecting that the signals output by the two signal output ends that are connected to any of the detection sub-circuits meet the normal output condition.

Optionally, said stopping outputting the signals to the two signal output ends that are connected to any of the detection sub-circuits comprises: stopping outputting signals to the two signal output ends that are connected to any of the detection sub-circuits and every other signal output end.

In yet another aspect, an embodiment of the present disclosure provides a drive circuit of a display device, comprising a gate drive circuit and a level shift circuit, wherein the level shift circuit comprises a level shift sub-circuit and at least one detection sub-circuit; the level shift sub-circuit is connected to at least two signal input ends and at least two signal output ends respectively and configured to convert the level of an input signal that is provided by each signal input end and then to output the level-converted input signal to the corresponding signal output end, each signal input end corresponding to one of the signal output ends; each detection sub-circuit is connected to two signal output ends and a feedback signal input end of the level shift sub-circuit respectively and configured to output a feedback signal with a first level to the level shift sub-circuit when detecting that signals output by the two signal output ends connected thereto do not meet a normal output condition; the level shift sub-circuit is further configured to stop outputting signals to two signal output ends that are connected to any of the detection sub-circuits when detecting the feedback signal with the first level sent by any of the detection sub-circuits; and the at least two signal output ends are connected to the gate drive circuit and configured to provide the gate drive circuit with a clock signal.

In still yet another aspect, an embodiment of the present disclosure provides a display device, comprising the drive circuit of a display device described above.

In summary, the embodiments of the present disclosure provide a level shift circuit, control method thereof, a display device and a drive circuit thereof. A detection sub-circuit is disposed in the level shift circuit, and the detection sub-circuit detects whether the signals output by the two signal output ends meet the normal output condition or not. When detecting that the signals do not meet the normal condition, the level shift sub-circuit may stop outputting the signals to the two signal output ends.

### BRIEF DESCRIPTION OF THE DRAWINGS

FIG. 1 is a schematic view of a structure of a level shift circuit according to an embodiment of the present disclosure;

FIG. 2 is a schematic view of a structure of another level shift circuit according to an embodiment of the present disclosure;

FIG. 3 is a waveform of an input signal provided by each signal input end according to an embodiment of the present disclosure;

FIG. 4 is a waveform of the signals output by each signal output end when the level shift circuit is in a normal working state according to an embodiment of the present disclosure;

FIG. 5 is a waveform of the signals output by each signal output end when the level shift circuit is not in a normal working state according to an embodiment of the present disclosure;

FIG. 6 is a schematic view of a structure of a comparator according to an embodiment of the present disclosure;

FIG. 7 is a flow chart of a control method of a level shift circuit according to an embodiment of the present disclosure; and

FIG. 8 is a schematic view of a structure of a drive circuit of a display device according to an embodiment of the present disclosure.

### DETAILED DESCRIPTION

To make the principle and advantages of the present disclosure clearer, the embodiments of the present disclosure will be further described in detail below in conjunction with the accompanying drawings.

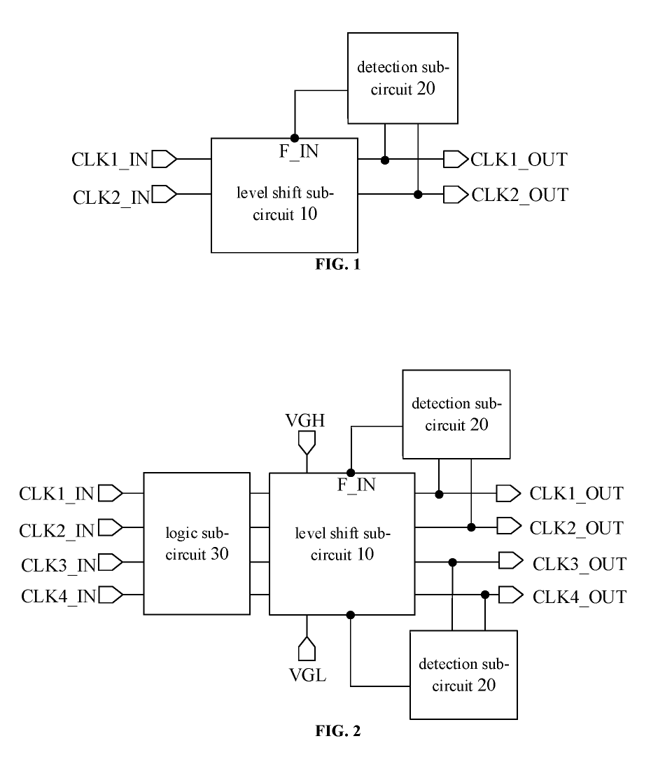

FIG. 1 is a schematic view of a structure of a level shift circuit provided by an embodiment of the present disclosure. As shown in FIG. 1, the level shift circuit may comprise a level shift sub-circuit 10 and at least one detection sub-circuit 20. For example, the level shift circuit illustrated by FIG. 1 comprises one detection sub-circuit 20.

The level shift sub-circuit 10 is connected to at least two signal input ends and at least two signal output ends respectively. Each signal input end corresponds to one of the signal output ends. For example, in the level shift circuit illustrated by FIG. 1, the level shift sub-circuit 10 is connected to two signal input ends CLK1_IN and CLK2_IN respectively and also connected to two signal output ends CLK1_OUT and CLK2_OUT. The signal input end CLK1_IN corresponds to the signal output end CLK1_OUT. The signal input end CLK2_IN corresponds to the signal output end CLK2_OUT.

As the level of a control signal required by a gate drive circuit is relatively higher, the level shift sub-circuit 10 may convert the level of an input signal that is provided by each signal input end. That is, an absolute value of the level of the input signal is increased, and the level-converted signal is output to the corresponding signal output end. For example, assuming that a level change range of the input signal provided by the signal input end CLK1_IN is 0-3.3 volt (V), the level shift sub-circuit 10 may convert the level of the input signal to broaden its level change range to be −8 V to 30 V. Then, the level-converted signal may be output to the signal output end CLK1_OUT.

Furthermore, each detection sub-circuit 20 may be connected respectively to two signal output ends and a feedback signal input end F_IN of the level shift sub-circuit 10. Each detection sub-circuit 20 is configured to compare signals output by the two signal output ends connected thereto and to detect whether the signals output by the two signal output ends meet a normal output condition or not. Each detection sub-circuit 20 may be further configured to output a feedback signal with a first level to the level shift sub-circuit 10 when detecting that the signals output by the two signal output ends connected thereto do not meet the normal output condition.

For example, in the level shift circuit illustrated by FIG. 1, the detection sub-circuit 20 may be connected respectively to the two signal output ends CLK1_OUT and CLK2_OUT and the feedback signal input end F_IN of the level shift sub-circuit 10, and may output the feedback signal with the first level to the level shift sub-circuit 10 when detecting that the signal output by the signal output end CLK1_OUT and the signal output by the signal output end CLK2_OUT does not meet the normal output condition.

The level shift sub-circuit 10 may be further configured to stop outputting signals to two signal output ends that are connected to any of the detection sub-circuits 20 when detecting the feedback signal with the first level sent by any of the detection sub-circuits 20, to avoid that the output signals that do not meet the normal output condition influence devices in the gate drive circuit. For example, in the level shift circuit illustrated by FIG. 1, the level shift sub-circuit 10 can stop outputting the signals to the signal output ends CLK1_OUT and CLK2_OUT when detecting the feedback signal with the first level sent by the detection sub-circuit 20.

In the embodiment of the present disclosure, when any of the two signal output ends that are connected to the detection sub-circuit 20 fails to work (for example, a signal wire connected to the signal output end is short-circuited with other signal wires), a waveform of the signal output by the signal output end may be abnormal. The detection sub-circuit 20 can then detect that the signals output by the two signal output ends connected thereto do not meet the normal output condition, and can provide the feedback signal to the level shift sub-circuit 10 to enable the level shift sub-circuit 10 to immediately stop outputting the signals to the two signal output ends. Thus, the devices in the gate drive circuit is protected.

To sum up, in the level shift circuit provided by the embodiment of the present disclosure, the detection sub-circuit is disposed in the level shift circuit to detect whether the signals output by the two signal output ends meet the normal output condition or not. When detecting that the signals do not meet the normal condition, the level shift sub-circuit may stop outputting the signals to the two signal output ends. Thus, the problems that an overcurrent protection chip in the related art is monotonous in detection mode and relatively poorer in protection effect may be solved. The gate drive circuit can be effectively protected.

FIG. 2 is a schematic view of a structure of another level shift circuit provided by an embodiment of the present disclosure. As shown in FIG. 2, a level shift sub-circuit 10 may be connected to at least one group of signal input ends and at least one group of signal output ends respectively.

Herein, each group of signal input ends may comprise two signal input ends. Input signals provided by the two signal input ends in each group of signal input ends may be complementary. Each group of signal output ends comprise two signal output ends. Each detection sub-circuit 20 may be connected to one group of signal output ends. Besides, in the at least one group of signal input ends, input signals provided by any two signal input ends are different in time sequence.

As the level shift sub-circuit 10 only converts the levels of the input signals, the frequency of each output signal should be the same as that of the corresponding input signal, and the phase of each output signal also should be the same as that of the corresponding input signal. It can be known that during the normal work of the level shift circuit, signals output by the two signal output ends connected to each detection sub-circuit 20 should be complementary. That is, a normal output condition is that the signals output by the two signal output ends are complementary.

Correspondingly, each detection sub-circuit 20 may be configured to detect whether the signals output by the two signal output ends connected thereto are complementary or not and to output a feedback signal with a first level to the level shift sub-circuit 10 when detecting that the signals output by the two signal output ends connected thereto are not complementary.

In the embodiment of the present disclosure, complementation of the two signals may mean that: at the same detection time, when the level of one signal is within a preset high-level range, the level of the other signal is within a preset low-level range; and when the level of one signal is within the preset low-level range, the level of the other signal is within the preset high-level range. A lower limit value of the preset high-level range may be more than an upper limit value of the preset low-level range.

Exemplarily, referring to FIG. 2, the level shift sub-circuit 10 may be connected to two groups of signal input ends and two groups of signal output ends respectively. A first group of signal input ends comprise two signal input ends CLK1_IN and CLK2_IN. A second group of signal input ends comprise two signal input ends CLK3_IN and CLK4_IN. A first group of signal output ends comprise two signal output ends CLK1_OUT and CLK2_OUT. A second group of signal output ends comprise two signal output ends CLK3_OUT and CLK4_OUT.

Correspondingly, the level shift circuit may comprise two detection sub-circuits 20. One of the two detection sub-circuits 20 may be connected to the two signal output ends CLK1_OUT and CLK2_OUT in the first group of the signal output ends, and may output the feedback signal with the first level to the level shift sub-circuit 10 when detecting that the signal output by the signal output end CLK1_OUT and the signal output by the signal output end CLK2_OUT are non-complementary. The other detection sub-circuit 20 of the two detection sub-circuits 20 may be connected to the two signal output ends CLK3_OUT and CLK4_OUT in the second group of the signal output ends, and may output the feedback signal with the first level to the level shift sub-circuit 10 when detecting that the signal output by the signal output end CLK3_OUT and the signal output by the signal output end CLK4_OUT are non-complementary.

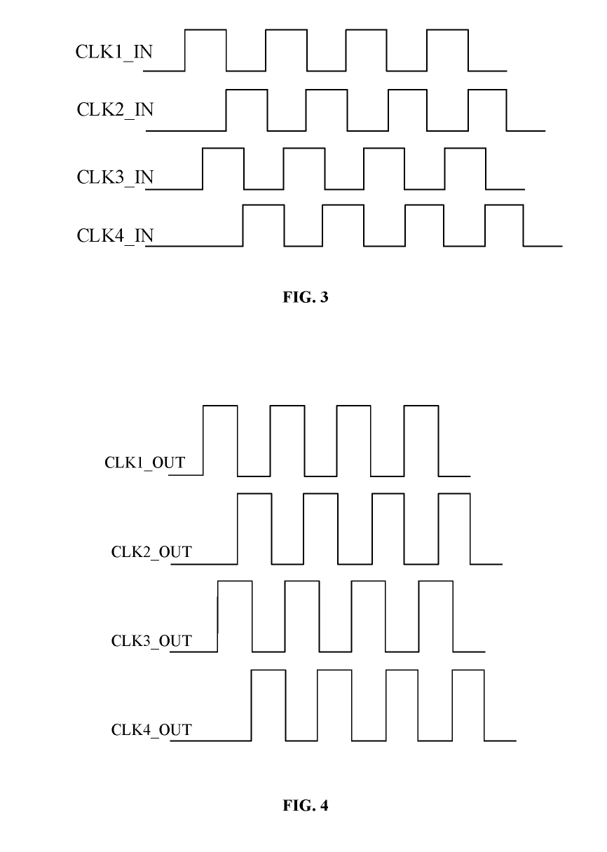

FIG. 3 is a waveform of an input signal provided by each signal input end provided by an embodiment of the present disclosure. It can be seen from FIG. 3 that the input signals provided by the two signal input ends CLK1_IN and CLK2_IN in the first group of signal input ends are complementary and the input signals provided by the two signal input ends CLK3_IN and CLK4_IN in the second group of signal input ends are complementary.

Optionally, as shown in FIG. 2, the level shift circuit may further comprise a logic sub-circuit 30 that is configured to connect at least two signal input ends with the level shift sub-circuit 10. That is, the level shift sub-circuit 10 is connected to the at least two signal input ends through the logic sub-circuit 30. The logic sub-circuit 30 may be an integrated chip and is configured to process the input signals provided by the signal input ends and then to provide the level shift sub-circuit 10 with the processed input signals. For example, the logic sub-circuit 30 may match the input signals provided by the signal input ends into signals that may be processed by the level shift sub-circuit 10.

Besides, it can be seen from FIG. 2 that the level shift sub-circuit 10 may be further connected to a first power supply end VGH and a second power supply end VGL. The level of a first power supply signal provided by the first power supply end VGH may be a third level (for example, 30 V). The level of a second power supply signal provided by the second power supply end VGL may be a fourth level (for example, −8 V). The third level may be a high level relative to the fourth level. The level shift circuit 10 may be controlled by the power supply signals provided by the two power supply ends to realize level conversion of the input signals.

Furthermore, the input signals provided by the two signal input ends of each group of signal input ends are the same in frequency but opposite in phase. Correspondingly, the normal output condition may be that the signals output by the two signal output ends are the same in frequency but opposite in phase.

Exemplarily, as shown in FIG. 3, the input signal provided by each signal input end may be a clock signal. The input signals provided by the two signal input ends CLK1_IN and CLK2_IN in the first group of signal input ends are the same in frequency but opposite in phase. The input signals provided by the two signal input ends CLK3_IN and CLK4_IN in the second group of signal input ends are the same in frequency but opposite in phase.

Assuming that in the level shift circuit illustrated by FIG. 2, the signal output end CLK1_OUT corresponds to the signal input end CLK1_IN, the signal output end CLK2_OUT corresponds to the signal input end CLK2_IN, the signal output end CLK3_OUT corresponds to the signal input end CLK3_IN, the signal output end CLK4_OUT corresponds to the signal input end CLK4_IN, waveform of the signals output by the signal output ends CLK1_OUT to CLK4_OUT that are connected to the level shift sub-circuit 10 may be as shown in FIG. 4 when the level shift circuit is in a normal working state. Through comparison between FIG. 3 and FIG. 4, it can be seen that when the level shift circuit is in the normal working state, the signals output by the two signal output ends in each group of signal output ends have broadened level change ranges, but the signals output by the two signal output ends are still satisfying the same in frequency but opposite in phase.

Correspondingly, each detection sub-circuit 20 may be configured to detect whether the signals output by the two signal output ends connected thereto are the same in frequency and phase or not, and to output the feedback signal with the first level to the level shift sub-circuit 10 when detecting that the signals output by the two signal output ends are different in any of the two parameters including frequency and phase.

Optionally, in the embodiment of the present disclosure, each detection sub-circuit 20 may further be configured to output the feedback signal with the second level to the level shift sub-circuit 10 when detecting that the signals output by the two signal output ends connected thereto meet the normal output condition.

The level shift sub-circuit 10 may be further configured to output signals to two signal output ends connected to any of the detection sub-circuits 20 when detecting the feedback signal with the second level sent by any of the detection sub-circuits 20.

Herein, the second level may be a high level or a low level relative to the first level, which will not be limited by the embodiment of the present disclosure.

Optionally, each detection sub-circuit 20 in the level shift sub-circuit may comprise a comparator.

Two input ends of the comparator may be respectively connected to two signal output ends. An output end of the comparator may be connected to a feedback signal input end F_IN of the level shift sub-circuit 10. The comparator may be configured to detect the levels of signals output by the two signal output ends connected thereto. The comparator may output a feedback signal with a first level to the level shift sub-circuit 10 when detecting that the levels of the signals output by the two signal output ends do not meet the normal output condition, and may output a feedback signal with a second level to the level shift sub-circuit 10 when detecting that the levels of the signals output by the two signal output ends meet the normal output condition.

The normal output condition may comprise that the level of the signal output by one signal output end is within a preset high-level range, and the level of the signal output by the other signal output end is within a preset low-level range. A lower limit value of the preset high-level range may be greater than an upper limit value of the preset low-level range.

In the embodiment of the present disclosure, the lower limit value of the preset low-level range may be the lowest level of the output signals when the level shift circuit works normally. The lowest level is generally a negative level. The upper limit value of the preset low-level range may be 20% (or any other percentage less than 1, which will not be limited by the embodiment of the present disclosure) of the lowest level of the output signals when the level shift circuit works normally. The upper limit value of the preset high-level range may be the highest level of the output signals when the level shift circuit works normally. The lower limit value of the preset high-level range may be 20% (or any other percentage less than 1) of the highest level of the output signals when the level shift circuit works normally.

Exemplarily, assuming that the lowest level of the output signals is −8 V when the level shift circuit works normally, the lower limit value of the preset low-level range may be −8 V and the upper limit value of the preset low-level range may be −1.6 V. Then, it can be known that the preset low-level range is −8 V to −1.6 V. Assuming that the highest level of the output signal is 30 V when the level shift circuit works normally, the upper limit value of the preset high-level range may be 30 V and the lower limit value of the preset high-level range may be 6 V. Then, it can be known that the preset high-level range is 6 V to 30 V.

Furthermore, assuming that the two signal output ends CLK1_OUT and CLK2_OUT are connected to the comparator, the comparator may compare the levels of the signals output by the signal output ends CLK1_OUT and CLK2_OUT with the preset high-level range 6 V to 30 V and the preset low-level range −8 V to −1.6 V respectively. If the comparator detects that the level of the signal output by one signal output end is within the range of 6V to 30 V and the level of the signal output by the other signal output end is within the range of −8 V to −1.6 V, the comparator may determine the levels of the signals output by the two signal output ends CLK1_OUT and CLK2_OUT meet the normal output condition, and therefore, may output the feedback signal with the second level to the level shift sub-circuit 10.

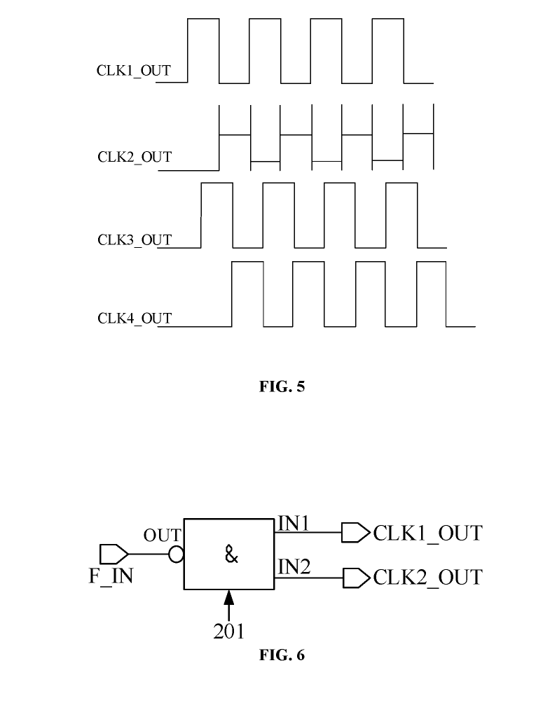

When the level shift circuit is not in the normal working state, for example, when a signal wire connected to the signal output end CLK2_OUT is short-circuited with other signal wires, the waveform of the signals output by the signal output ends CLK1_OUT to CLK4_OUT that are connected to the level shift sub-circuit 10 may be as shown in FIG. 5. Through comparison between FIG. 4 and FIG. 5, it can be seen that the level of the signal output by the signal output end CLK2_OUT changes abnormally. The level of the signal output by the signal output end CLK2_OUT in a high-level continuing phase is lower than a high level during a normal output, and the level of the signal output by the signal output end CLK2_OUT in a low-level continuing phase is higher than a low level during the normal output. Assuming that the level of the signal output by the signal output end CLK2_OUT in the high-level continuing phase is 5 V, and the level of the signal output by the signal output end CLK1_OUT in the high-level continuing phase is −7 V, the comparator may detect that the level of the signal output by the signal output end CLK1_OUT is within the preset low-level range while the level of the signal output by the signal output end CLK2_OUT is not within the preset high-level range. Thus, the comparator may determine that the levels of the signals output by the first group of signal output ends do not meet the normal output condition and may output the feedback signal with the first level to the level shift sub-circuit 10.

Optionally, FIG. 6 is a schematic view of a structure of a comparator provided by an embodiment of the present disclosure. As shown in FIG. 6, the comparator may comprise a NAND gate 201, of which two input ends are connected to one group of signal output ends of a level shift sub-circuit 10 and an output end is connected to a feedback signal input end F_IN of the level shift sub-circuit 10.

Referring to FIG. 6, a first input end IN1 of the NAND gate 201 may be connected to the signal output end CLK1_OUT. A second input end IN2 of the NAND gate 201 may be connected to the signal output end CLK2_OUT. The output end OUT of the NAND gate 201 may be connected to the feedback signal input end F_IN of the level shift sub-circuit 10. The NAND gate may output feedback signals with different levels to the level shift sub-circuit 10. For example, the NAND gate may output the feedback signal with the first level or the feedback signal with the second level.

Optionally, in the embodiment of the present disclosure, the NAND gate 201 may determine that an input of the first input end IN1 is 1 when the level of the signal output by the signal output end CLK1_OUT is within the preset high-level range, and may determine that an input of the second input end IN2 is 0 when the level of the signal output by the signal output end CLK2_OUT is within the preset low-level range. Besides, the NAND gate 201 may determine the level of the outputted feedback signal in accordance with the levels of the two output signals. Table 1 is a truth table of the NAND gate 201. It can be known from the truth table that when the signal output by one of the two signal output ends connected to the NAND gate 201 is within the high-level range and the signal output by the other signal output end is within the preset low-level range, an output of the output end OUT of the NAND gate 201 is 1; and when the signals output by the two signal output ends are within the preset high-level range or the preset low-level range, the output of the output end OUT of the NAND gate 201 is 0.

Assuming that the first level is a low level relative to the second level, it can be known from Table 1 that when the output of the output end OUT of the NAND gate 201 is 1 (that is, the level of the feedback signal output by the output end OUT of the NAND gate 201 is the second level), the level shift sub-circuit 10 may determine that the two output signals connected to the NAND gate 201 meet the normal output condition; and when the output of the output end OUT of the NAND gate 201 is 0 (that is, the level of the feedback signal output by the output end OUT of the NAND gate 201 is the first level), the level shift sub-circuit 10 may determine that the two output signals connected to the NAND gate 201 do not meet the normal output condition.

TABLE 1

| IN1 | IN2 | OUT |
|---|---|---|
| 0 | 0 | 0 |
| 1 | 1 | 0 |
| 1 | 0 | 1 |
| 0 | 1 | 1 |

Exemplarily, referring to FIG. 6, assuming that the level of the signal output by the signal output end CLK1_OUT is 8 V, and the level of the signal output by the signal output end CLK2_OUT is −2 V, the NAND gate 201 may determine that an input of the first input end IN1 is 1 and an input of the second input end IN2 is 1. It can be known from Table 1 that at this time, the output of the output end OUT of the NAND gate 201 is 0 (that is, the level of the feedback signal output by the output end OUT of the NAND gate 201 is the first level). Then, the level shift sub-circuit 10 may judge that the output signals do not meet the normal output condition, and therefore, may stop outputting the signals to the two signal output ends CLK1_OUT and CLK2_OUT.

Assuming that the level of the signal output by the signal output end CLK1_OUT is 8 V and the level of the signal output by the signal output end CLK2_OUT is −4 V, the NAND gate 201 may determine that the input of the first input end IN1 is 1 and the input of the second input end IN2 is 0. It can be known from Table 1 that at this time, the output of the output end OUT of the NAND gate 201 is 1 (that is, the level of the feedback signal output by the output end OUT of the NAND gate 201 is the second level). Then, the level shift sub-circuit 10 may judge that the output signals meet the normal output condition, and therefore, may continue to output a signal to a gate drive circuit.

Optionally, in the embodiment of the present disclosure, the level shift sub-circuit 10 may be further configured to stop outputting signals to all the signal output ends connected thereto when detecting the feedback signal with the first level output by any of the detection sub-circuits 20. Correspondingly, the level shift sub-circuit 10 may be further configured to output signals to each signal output end connected thereto when detecting the feedback signals with the second level output by all the detection sub-circuits 20.

When the signals output by the two signal output ends connected to any of the detection sub-circuits 20 do not meet the normal output condition, output of the signals to all the signal output ends is stopped. Thus, the output signals which do not meet the normal output condition may be effectively prevented from influencing the device in the gate drive circuit. The reliability of the level shift circuit may be improved.

Optionally, an overcurrent protection chip may be further disposed in the level shift sub-circuit 10 and may detect current of a signal output by the level shift sub-circuit 10. When detecting that the current of the output signal exceeds threshold current (for example, 150-200 mA), the overcurrent protection chip may start overcurrent protection. For example, the overcurrent protection chip may stop outputting a control signal to the gate drive circuit to avoid damaging the device in the gate drive circuit. The protection effect of the level shift circuit on the gate drive circuit may be effectively improved via the overcurrent protection chip and the detection sub-circuits 20.

To sum up, according to the level shift circuit provided by the embodiment of the present disclosure, the detection sub-circuit is disposed in the level shift circuit to detect whether the signals output by the two signal output ends meet the normal output condition or not. When detecting that the signals do not meet the normal condition, the level shift sub-circuit may stop outputting signals to the two signal output ends. Thus, the problems in the related art that the overcurrent protection chip is monotonous in detection mode and relatively poorer in protection effect may be solved. The gate drive circuit may be effectively protected.

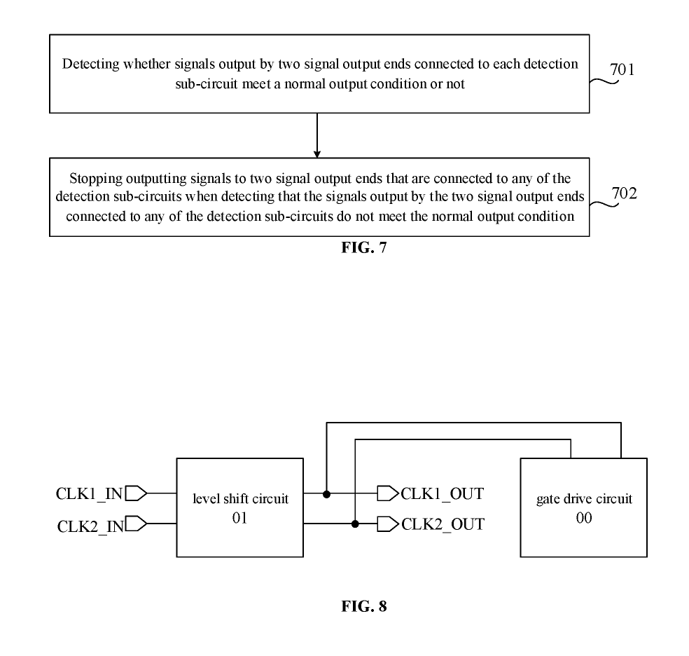

FIG. 7 is a flow chart of a control method of a level shift circuit, provided by an embodiment of the present disclosure. The method may be applied to the level shift circuit as shown in FIG. 1 or FIG. 2. As shown in FIG. 7, the control method may comprise the following operating processes.

In step 701, whether signals output by two signal output ends connected to each detection sub-circuit meet a normal output condition or not is detected.

In step 702, outputting signals to two signal output ends that are connected to any of the detection sub-circuits when detecting that the signals output by the two signal output ends connected to any of the detection sub-circuits do not meet the normal output condition is stopped.

To sum up, the control method of the level shift circuit, provided by the embodiment of the present disclosure, may detect whether the signals output by the two signal output ends connected to each detection sub-circuit meet the normal output condition or not, and when detecting that the signals do not meet the normal condition, may stop outputting the signals to the two signal output ends. Thus, the problems in the related art that the overcurrent protection chip is monotonous in detection mode and relatively poorer in protection effect may be solved. The gate drive circuit may be effectively protected.

Optionally, a level shift sub-circuit in the level shift circuit is connected to at least one group of signal input ends and at least one group of signal output ends respectively. Each group of signal input ends comprise two signal input ends. Input signals provided by the two signal input ends in each group of signal input ends are complementary. Correspondingly, the normal output condition may include that the signals output by the two signal output ends are complementary.

For example, in the embodiment of the present disclosure, input signals provided by the two signal input ends in each group of signal input ends are the same in frequency but opposite in phase. Thus, the normal output condition may include that the signals output by the two signal output ends are the same in frequency but opposite in phase.

Optionally, when the detection sub-circuit is a comparator, the levels of the signals output by the two signal output ends connected to the comparator may be detected by the comparator. Whether the two output signals meet the normal output condition or not is judged in accordance with the levels of the two output signals. The normal output condition may include the level of the signal output by one signal output end is within a preset high-level range and the level of the signal output by the other signal output end is within a preset low-level range.

The processes of detecting the levels of the signals output by the two signal output ends connected thereto and judging whether the signals output by the two signal output ends meet the normal output condition or not by the comparator may refer to the foregoing embodiments and will not be repeated herein.

Optionally, in the embodiment of the present disclosure, after the above step 701, the control method may further comprise the following step.

In step 703, signals are output to two signal output ends that are connected to any of the detection sub-circuits when detecting that the signals output by the two signal output ends that are connected to any of the detection sub-circuits meet the normal output condition.

Optionally, in the embodiment of the present disclosure, the operation of the step 702 may comprise: stopping outputting signals to the two signal output ends that are connected to any of the detection sub-circuits and every other signal output end.

For example, when the signals output by the two signal output ends connected to any of the detection sub-circuits do not meet the normal output condition is detected, output of the signals to all the signal output ends of the level shift circuit may be stopped to effectively protect the gate drive circuit.

Alternatively, the operation in the step 703 may comprise: outputting signals to two signal output ends that are connected to any of the detection sub-circuits when detecting the signals output by the two signal output ends connected to each detection sub-circuit meet the normal output condition.

To sum up, by use of the control method of the level shift circuit, provided by the embodiment of the present disclosure, whether the signals output by the two signal output ends connected to each detection sub-circuit meet the normal output condition or not may be detected, and when detecting that the signals do not meet the normal condition, output of the signals to the two signal output ends is stopped. The problems in the related art that an overcurrent protection chip is monotonous in detection mode and relatively poorer in protection effect may be solved. The gate drive circuit may be effectively protected.

An embodiment of the present disclosure provides a drive circuit of a display device. As shown in FIG. 8, the drive circuit may comprise a gate drive circuit 00 and a level shift circuit 01. The level shift circuit 01 may be the level shift circuit as shown in FIG. 1 or FIG. 2.

Herein, at least two signal output ends of the level shift circuit 01 are connected to the gate drive circuit 00. At least two signal output ends of the level shift circuit 01 are configured to provide a clock signal for the gate drive circuit 00.

Optionally, in the embodiment of the present disclosure, the gate drive circuit 00 may be connected to at least two signal output ends of the level shift circuit 01 through at least two signal wires. The plurality of signal wires is generally located at an edge of the display device.

When the edge of the display device is abraded, the signal wires may be short-circuited. If the level shift circuit does not stop outputting signals to the signal output ends at this time, the temperature of the gate drive circuit may rise to damage the gate drive circuit and even a display panel in the display device.

However, the detection sub-circuit 20 which may compare the signals output by the two signal output ends connected thereto is disposed in the level shift circuit provided by the embodiment of the present disclosure. When any of the signal output ends fails to work (for example, the signal wire connected to the signal output end is short-circuited with other signal wires), a waveform of the signal output by the signal output end becomes abnormal. The detection sub-circuit may then detect that the signals output by the two signal output ends connected thereto do not meet the normal output condition and may provide feedback signals to the level shift sub-circuit 10 to enable that the level shift sub-circuit 10 stops immediately outputting signals to the two signal output ends, such that devices in the gate drive circuit may be protected.

The embodiments of the present disclosure provide a display device. The display device may include: a drive circuit of the display device. The drive circuit of the display device includes: a gate drive circuit and a level shift circuit shown in FIG. 1 or FIG. 2. The display device may be a liquid crystal panel, an electronic paper, an OLED panel, a mobile phone, a tablet, a TV, a display, a laptop computer, a digital photo frame, a navigator, or any other products or parts with display functionality.

The foregoing examples are only some embodiments of the present disclosure, and are not intended to limit the present disclosure. Within the spirit and principles of the disclosure, any modifications, equivalent substitutions, improvements, etc., are within the scope of protection of the present disclosure.

What is claimed is:

1. A level shift circuit, comprising a level shift sub-circuit and at least one detection sub-circuit, wherein
the level shift sub-circuit is connected to at least two signal input ends and at least two signal output ends respectively and configured to convert the level of an input signal that is provided by each signal input end and then to output the level-converted input signal to the corresponding signal output end, each signal input end corresponding to one of the signal output ends;
each detection sub-circuit is connected to two signal output ends and a feedback signal input end of the level shift sub-circuit respectively and configured to output a feedback signal with a first level to the level shift sub-circuit when detecting that signals output by the two signal output ends connected thereto do not meet a normal output condition; and
the level shift sub-circuit is further configured to stop outputting the signals to the two signal output ends that are connected to any of the detection sub-circuits when detecting the feedback signal with the first level sent by any of the detection sub-circuits.

2. The level shift circuit according to claim 1, wherein the level shift sub-circuit is connected to at least one group of signal input ends and at least one group of signal output ends respectively, each group of signal input ends comprising two signal input ends, input signals that are provided by the two signal input ends of each group of signal input ends being complementary, each group of signal output ends comprising two signal output ends, and each detection sub-circuit is connected to one group of signal output ends respectively; and
the normal output condition includes that the signals output by the two signal output ends are complementary.

3. The level shift circuit according to claim 2, wherein input signals that are provided by the two signal input ends of each group of signal input ends are the same in frequency but opposite in phase; and
the normal output condition includes that the signals output by the two signal output ends are the same in frequency but opposite in phase.

4. The level shift circuit according to claim 2, wherein the level shift sub-circuit is connected to two groups of signal input ends and two groups of signal output ends respectively; and
the level shift circuit comprises two detection sub-circuits each of which is connected to one group of signal output ends respectively.

5. The level shift circuit according to claim 1, wherein each detection sub-circuit is further configured to output a feedback signal with a second level to the level shift sub-circuit when detecting that the signals output by the two signal output ends connected thereto meet the normal output condition; and
the level shift sub-circuit is further configured to output signals to two signal output ends that are connected to any of the detection sub-circuits when detecting the feedback signal with the second level sent by any of the detection sub-circuits.

6. The level shift circuit according to claim 1, wherein each detection sub-circuit comprises a comparator:
two input ends of the comparator are respectively connected to two signal output ends, an output end of the comparator is connected to a feedback signal input end of the level shift sub-circuit, the comparator is configured to detect the levels of signals output by the two signal output ends, output a feedback signal with a first level to the level shift sub-circuit when detecting that the levels of the signals output by the two signal output ends do not meet the normal output condition, and output a feedback signal with a second level to the level shift sub-circuit when detecting that the levels of the signals output by the two signal output ends meet the normal output condition; and
the normal output condition includes that the level of the signal output by one signal output end is within a high-level range and the level of the signal output by the other signal output end is within a low-level range.

7. The level shift circuit according to claim 6, wherein the comparator comprises a NAND gate; and
two input ends of the NAND gate are respectively connected to two signal output ends, and an output end of the NAND gate is connected to the feedback signal input end of the level shift sub-circuit.

8. The level shift circuit according to claim 1, wherein the level shift sub-circuit is further configured to stop outputting signals to all the signal output ends when detecting the feedback signal with the first level sent by any of the detection sub-circuits.

9. The level shift circuit according to claim 1, further comprising a logic sub-circuit, wherein
the level shift sub-circuit is connected to the at least two signal input ends through the logic sub-circuit, and the logic sub-circuit is configured to process the input signal provided by each signal input end and then to provide the level shift sub-circuit with the processed input signals.

10. The level shift circuit according to claim 1, wherein the level shift sub-circuit is further connected to a first power supply end and a second power supply end respectively, the first power supply end being used to provide a first power supply signal with a third level, the second power supply end being used to provide a second power supply signal with a fourth level, and the third level being a high level relative to the fourth level; and
the level shift sub-circuit is configured to convert the level of the input signal provided by each signal input end based on the first power supply signal and the second power supply signal.

11. A control method of a level shift circuit which comprises a level shift sub-circuit and at least one detection sub-circuit; the level shift sub-circuit is connected to at least two signal input ends and at least two signal output ends respectively, and each detection sub-circuit is connected to two signal output ends and the level shift sub-circuit respectively, comprising:
detecting whether signals output by the two signal output ends that are connected to each detection sub-circuit meet a normal output condition or not; and
stopping outputting signals to two signal output ends that are connected to any of the detection sub-circuit when detecting that the signals output by two signal output ends that are connected to any of the detection sub-circuit do not meet the normal output condition.

12. The control method according to claim 11, wherein the level shift sub-circuit is connected to at least one group of signal input ends and at least one group of signal output ends respectively, each group of signal input ends comprising two signal input ends, input signals that are provided by the two signal input ends of each group of signal input ends being complementary; and
the normal output condition includes that the signals output by the two signal output ends are complementary.

13. The control method according to claim 11, input signals that are provided by the two signal input ends of each group of signal input ends are the same in frequency but opposite in phase; and
the normal output condition includes that the signals output by the two signal output ends are the same in frequency but opposite in phase.

14. The control method according to claim 11, after said detecting whether the signals output by the two signal output ends that are connected to each detection sub-circuit meet the normal output condition or not, further comprising:
outputting signals to two signal output ends that are connected to any of the detection sub-circuits when detecting that the signals output by the two signal output ends that are connected to any of the detection sub-circuits meet the normal output condition.

15. The control method according to claim 11, said stopping outputting the signals to the two signal output ends that are connected to any of the detection sub-circuits comprises:
stopping outputting signals to the two signal output ends that are connected to any of the detection sub-circuits and every other signal output end.

16. A drive circuit of a display device, comprising a gate drive circuit and a level shift circuit, wherein the level shift circuit comprises a level shift sub-circuit and at least one detection sub-circuit:
the level shift sub-circuit is connected to at least two signal input ends and at least two signal output ends respectively and configured to convert the level of an input signal that is provided by each signal input end and then to output the level-converted input signal to the corresponding signal output end, each signal input end corresponding to one of the signal output ends;
each detection sub-circuit is connected to two signal output ends and a feedback signal input end of the level shift sub-circuit respectively and configured to output a feedback signal with a first level to the level shift sub-circuit when detecting that signals output by the two signal output ends connected thereto do not meet a normal output condition;
the level shift sub-circuit is further configured to stop outputting signals to two signal output ends that are connected to any of the detection sub-circuits when detecting the feedback signal with the first level sent by any of the detection sub-circuits; and
the at least two signal output ends are connected to the gate drive circuit and configured to provide the gate drive circuit with a clock signal.

17. A display device, comprising the drive circuit according to claim 16.
